(19) United States
(12) Patent Application Publication
(10) Pub. No.: US 2012/0305062 A1
(43) Pub. Date: Dec. 6, 2012

(54) SOLAR CELL

(75) Inventor: Shigeo YATA, Ogaki-shi (JP)

(73) Assignee: SANYO Electric Co., Ltd., Moriguchi-shi (JP)

(21) Appl. No.: 13/585,497

(22) Filed: Aug. 14, 2012

Related U.S. Application Data
(63) Continuation of application No. PCT/JP2011/051781, filed on Jan. 28, 2011.

(30) Foreign Application Priority Data
Feb. 26, 2010 (JP) 2010-041482
Jun. 25, 2010 (JP) 2010-144866

(51) Int. Cl. H01L 31/0687

(52) U.S. Cl. 136/255

(57) ABSTRACT

Disclosed is a solar cell with the ability to extract more photogenerated carriers while improving power generation efficiency. The solar cell (10) includes a light-receiving surface electrode layer (2), a first photoelectric conversion section (31) laminated on the light-receiving surface electrode layer (2), a reflective layer (32) laminated on the first photoelectric conversion section (31) and having an SiO layer (32b) and silicon layers (32a, 32c), a second photoelectric conversion (33) laminated on the reflective layer (32), and a rear-side electrode layer (4) laminated on the second photoelectric conversion section (33).

### CROSS-REFERENCE TO RELATED APPLICATION

The present application is a continuation application of International Application No. PCT/JP2011/051781, filed Jan. 28, 2011, the entire contents of which are incorporated herein by reference and priority to which is hereby claimed. The PCT/JP2011/051781 application claimed the benefit of the date of the earlier filed Japanese Patent Applications No. 2010-041482 filed Feb. 26, 2010 and No. 2010-144866, filed Jun. 25, 2010, the entire contents of which are incorporated herein by reference, and priority to which is hereby claimed.

### BACKGROUND

1. Technical Field

The present invention relates to a solar cell having a reflective layer to reflect a portion of incident light.

2. Background Art

Solar cells are expected to be a new energy source as they are capable of directly converting the clean and inexhaustible source energy of sunlight into electricity.

In general, a solar cell includes a photoelectric conversion section provided between a transparent electrode layer disposed on the light-incident side and a rear-side electrode layer disposed on the opposite side of light incidence, and absorbs incoming light incident on the solar cell to create photogenerated carriers.

It is conventionally known that a laminated body consisting of a plurality of photoelectric conversion sections is provided so that a large part of incident light can contribute to photoelectric conversion. Such multiple photoelectric conversion sections serve to guide a portion of light, which has been transmitted through the photoelectric conversion sections on the light-incident side without contributing to photoelectric conversion, to contribute to photoelectric conversion by other photoelectric conversion sections, whereby a larger amount of light can be absorbed by the photoelectric conversion sections. As a result, a larger number of photogenerated carriers can be created in the photoelectric conversion sections, which leads to improvement of the power generating efficiency of the solar cell.

To further improve the power generating efficiency, it is effective to increase the photogenerated carries created in the photoelectric conversion sections. Therefore, in the Patent Document 1, there is disclosed a solar cell which includes a low refractive index layer made of silicon oxide (SiO). With this structure, a portion of the incident light is reflected to enter the photoelectric conversion section on the light-incident side, while a portion of the incident light reflected, for example, from the rear-side electrode layer is re-reflected by other photoelectric conversion section on the side of the rear-side electrode and confined therein.
Patent Document 1: Japanese Patent Laid-Open Publication No. 2003-258279

Recently, however, further improvement of the power generation efficiency has been sought in solar cells. When the low refractive index layer made of silicon oxide (SiO) is used, contact resistance against the adjacent photoelectric conversion section is increased, which leads to the loss of photogenerated carriers.

The present invention is made to solve the above problem, and aims to provide a solar cell with improved power generation efficiency.

### SUMMARY

A solar cell according to the present invention includes a light-receiving surface electrode layer, a first photoelectric conversion section laminated on the light-receiving surface electrode layer, a reflective layer laminated on the first photoelectric conversion layer and having an SiO layer and a silicon layer, a second photoelectric conversion section laminated on the reflective layer, and a rear-side electrode layer laminated on the second photoelectric conversion section.

According to the present invention, a solar cell capable of improving power generation efficiency by restricting carrier loss of photogenerated carriers is provided.

### BRIEF DESCRIPTION OF THE DRAWINGS

A preferred embodiment of the present invention will be described in further detail based on the following drawings, wherein:

FIG. 1 is a sectional view of a solar cell 10 according to a first embodiment (Example 1) of the present invention;

FIG. 2 is a sectional view of a solar cell 10 according to a second embodiment of the present invention;

FIG. 3 is a sectional view of a solar cell 10 according to Example 2 of the present invention;

FIG. 4 is a sectional view of a solar cell 10 according to Example 3 of the present invention; and

FIG. 5 is a sectional view of a solar cell 10 according to Comparative Example of the present invention.

### DETAILED DESCRIPTION

Embodiments of the present invention will be described with reference to the attached drawings. In the drawings, the same or like reference numerals have been used throughout to identify identical or similar elements. It is to be understood, however, that these drawings are shown only schematically, and measurement ratios or the like are different from actual measurements. Specific measurements or the like should be estimated based on the description below. Also, it goes without saying that several relationships or ratios of measurements are not the same throughout the drawings.

### First Embodiment

### <Solar Cell Configuration>

A configuration of a solar cell according to a first embodiment of the present invention will be described below with reference to FIG. 1.

FIG. 1 is a sectional view of a solar cell 10 according to the first embodiment of the present invention.

The solar cell 10 is configured to include a substrate 1, a light-receiving surface electrode layer 2, a laminated body 3, and a rear-side electrode layer 4 which are laminated on each other in this order from the light-receiving surface to the rear side.

The substrate 1 has a light transmitting nature and is made of a light transmitting material such as glass or plastic.

The light receiving surface electrode layer 2 is laminated on the substrate 1 and is electrically conductive and transmits light. The light receiving surface electrode layer 2 is made of a metal oxide, such as tin oxide (SnO₂), Zinc Oxide (ZnO), Indium Oxide (In₂O₃), or titanium oxide (TiO₂). It is noted that such metal oxides may be doped with fluorine (F), tin (Sn), aluminum (Al), iron (Fe), gallium (Ga), niobium (Nb) or the like.

The laminated body 3 is provided between the light-receiving surface electrode layer 2 and the rear-side electrode layer 4. The laminated body 3 includes a first photoelectric conversion section 31, a reflective layer 32, and a second photoelectric conversion section 33.

The first photoelectric conversion section 31, the reflective layer 32, and the second photoelectric conversion section 33 are sequentially laminated in this order from the side of the light-receiving surface electrode layer 2.

The first photoelectric conversion section 31 creates photogenerated carriers from incident light coming from the side of the light-receiving surface electrode layer 2. The first photoelectric conversion section 31 has a pin junction formed by laminating a p-type amorphous silicon layer 31a, an i-type amorphous silicon layer 31b, and an n-type amorphous silicon layer 31c in this order from the side of the substrate 1.

The reflective layer 32 reflects a portion of light transmitted through the first photoelectric conversion portion 31 to the side of the first photoelectric conversion section 31. The'reflective layer 32 includes a first layer 32a, an intermediate layer 32b, and a second layer 32c.

The first layer 32a, the intermediate layer 32b, and the second layer 32c are laminated sequentially and in contact with each other from the side of the first photoelectric conversion section 31. Therefore, the first layer 32a is formed in contact with the first photoelectric conversion section 31.

The intermediate layer 32b is made by using n-type amorphous silicon oxide (SiO) as a major light transmitting and conductive material. SiO having a low refractive index to reflect a larger amount of light to the first photoelectric conversion section 31, and a second photoelectric conversion section 33 which will be described later, is used here. It should be noted that since the reflectivity becomes larger as the difference in refractive index between contacting surfaces is increased, it is preferable to set the refractive index of SiO to less than 2.4, considering that the refractive index of a silicon-based material for 550 nm wavelength of light is about 4.3, and the intermediate layer 32b having a refractive index of 2.2 is used here. It is noted that the refractive index of SiO can be controlled by adjusting the amount of oxygen in the film, so the refractive index of the SiO film is lowered by increasing the amount of oxygen. It is also noted that the intermediate layer 32b has a film thickness of 50 nm, but is preferably set from 30 to 150 nm.

The second layer 32c is formed on and in contact with the intermediate layer 32b.

For the first layer 32a, a material having a smaller contact resistance against the first photoelectric conversion section 31 than that between SiO used for the intermediate layer 32b and the first photoelectric conversion section 31 is mainly used. Namely, the material constituting the first layer 32a is selected so that the contact resistance between the first photoelectric conversion section 31 and the first layer 32a is less than the contact resistance obtained when the first photoelectric conversion section 31 and the intermediate layer 32b are directly in contact with each other.

Similarly, for the second layer 32c, a material having a smaller contact resistance against the second photoelectric conversion section 33 than the contact resistance between the SiO used for the intermediate layer 32b and the second photoelectric conversion section 33 is mainly used. Namely, the material constituting the second layer 32c is selected so that the contact resistance between the second photoelectric conversion section 33 and the second layer 32c is less than the contact resistance obtained when the second photoelectric conversion section 33 and the intermediate layer 32b are directly in contact with each other.

In this embodiment, intrinsic crystalline silicon is used to make the first layer 32a and the second layer 32c. In this case, a film thickness of both the first layer 32a and the second layer 32c is set to 30 nm, but is preferably from 10 to 50 nm.

It is noted that in the first embodiment of the present invention, the first layer 32a and the second layer 32c are examples of “Si layers” of the present invention, and the intermediate layer 32b is an example of an “n SiO layer” of the present invention.

It is also noted that the material constituting the first layer 32a and the second layer 32c is preferably selected so that the resistance between both ends of the laminated body 3 including the first layer 32a and the second layer 32c is smaller than that between both ends of the laminated body 3 without the first layer 32a and second layer 32c.

The second photoelectric conversion section 33 converts incident light coming from the side of the light-receiving surface electrode layer 2 and transmitted through the first photoelectric conversion section 31 into photogenerated carriers. The second photoelectric conversion section 33 has a pin junction formed by laminating a p-type crystalline silicon layer 33a, an i-type crystalline silicon layer 33b, and an n-type crystalline silicon layer 33c in this order from the side of the substrate 1.

The rear-side electrode layer 4 consists of one or more layers that are electrically conductive. A material such as ZnO or silver (Ag) may be used to form the rear-side electrode. In this embodiment, the rear-side electrode layer is formed by laminating a ZnO-containing layer and an Ag-containing layer from the side of the laminated body 3, but it is not limited thereto and the rear-side electrode layer 4 may only include the Ag-containing layer.

### <Effects>

In the solar cell 10 according to the first embodiment of the present invention, the reflective layer 32 consists of the first layer 32a, the intermediate layer 32b, and the second layer 32c. The first layer 32a is formed between the SiO intermediate layer 32b and the first photoelectric conversion section 31, or the second layer 32c is formed between the SiO intermediate layer 32b and the second photoelectric conversion section 33. Therefore, the power generation efficiency of the solar cell 10 is improved. Such an effect will be described in more detail below.

(1) By disposing the intermediate layer 32b between the first layer 32a and the second layer 32c of the reflective layer 32, the following effects are provided:

(a) Diffusion of oxygen from the SiO-based intermediate layer 32 to the first and/or second photoelectric conversion sections 31, 33 is inhibited by the silicon-based first and second layers 32a, 32c. As a result, lowering of the power generation efficiency due to deterioration of film quality by the diffusion of oxygen to the first and second photoelectric conversion sections 31, 33 can be restricted.

(b) Since the silicon-based first layer 32a has a higher refractive index than the SiO-based intermediate layer 32b, it is possible to reflect light to the side of the first layer 32a when the light is incident on the interface between the first layer 32a and the intermediate layer 32b from the side of the first layer 32a. Namely, the light can be re-directed to the first photoelectric conversion section 31, so that a larger amount of light can contribute to photoelectric conversion.

Similarly, the silicon-based second layer 32c also has a higher refractive index than the SiO-based intermediate layer 32b, it is possible to reflect light toward the side of the second layer 32c when the light is incident on the interface between the second layer 32c and the intermediate layer 32b from the side of the second layer 32c. Namely, light can be re-directed to the second photoelectric conversion section 33, so that a larger amount of light can contribute to photoelectric conversion.

(c) The intermediate layer 32b and the first photoelectric conversion section 31 being in direct contact with each other is prevented. This leads to restriction of the increase of series resistance of the solar cell 10 due to the high contact resistance at the interface between SiO and the photoelectric conversion section.

As the refractive index at the interface between the intermediate layer 32b and the first photoelectric conversion section 31 or the intermediate layer 32b and the second photoelectric conversion section 33 is increased, the short-circuit current generated in the solar cell 10 is increased, and the decrease of fill factor (F. F.) of the solar cell 10 due to the increase of series resistance is restricted. Thus, the power generation efficiency of the solar cell 10 is improved. With this configuration, the decrease of the fill factor of the solar cell 10 due to the increase of the series resistance in the entire solar cell 10 can be restricted, while the refractive index of the reflective layer 32 can be increased.

(2) The refractive index of the intermediate layer 32b for 550 nm wavelength of light is set to less than 2.4. Therefore, the reflectivity of the interface between the intermediate layer 32b and silicon having a refractive index of about 4.3 can be at least 8%. Consequently, a larger amount of light can be incident on the first photoelectric conversion section 31 made of amorphous silicon, which is the same effect as that obtained in the case of substantially increasing the thickness of the first photoelectric conversion section 31. As a result, photodeterioration of the first photoelectric conversion section 31, which becomes more of a problem as the section is thicker, can be restricted, and the decrease of photogenerated carriers created in the first photoelectric conversion section 31 is prevented.

(3) The intermediate layer 32b is amorphous, so that the refractive index can be smaller than that of a crystalline layer. The difference of refractive index compared to the silicon-based n-type amorphous silicon layer 31c or the second layer 32c is bigger, which produces a larger reflecting effect.

(4) The first layer 32a and the second layer 32c are made of intrinsic silicon. As a result, the following effects are provided.

(a) Diffusion of electrically conductive impurities from the first and second layers 32a, 32c to the first and second photoelectric conversion sections 31, 33 is prohibited. As a result, the decrease of power generation efficiency due to the deterioration of film quality that might occur when the impurities diffuse in the first and second photoelectric conversion sections 31, 33 can be prevented. In addition, as to the diffusion of oxygen from the SiO-based intermediate layer 32b, the oxygen diffusion toward the first and second photoelectric conversion sections 31, 33 can be effectively prevented by the fact that the first and second layers 32a, 32c are intrinsic.

(b) Absorption of light by the first layer 32a and the second layer 32c can be decreased compared to that of the one-conductivity type silicon. With the decrease of light absorption by the first layer 32a and the second layer 32c, a larger amount of light can be transmitted to contribute to power generation.

With the first layer 32a and the second layer 32c made of intrinsic silicon, the decrease of power generation efficiency due to deterioration of film quality caused by the diffusion of impurities in the first and second photoelectric conversion sections 31, 33 can be prevented, while the loss caused by absorption of light in the first layer 32a and the second layer 32c is restricted.

(5) The first layer 32a is crystalline, so that it serves as an underlying layer and contributes to the increase of crystalline components in the SiO-based intermediate layer 32b. As a result, the electrical conductivity can be strengthened by the increased amount of crystal components in SiO.

(6) The second layer 32c is made of intrinsic crystalline silicone. When the second photoelectric conversion section 33 is made of crystal silicone, crystal growth of the second photoelectric conversion section 33 can proceed, and proceeds well by using the second layer 32c as the underlying layer. As a result, the film quality of the second photoelectric conversion section 33 is improved, whereby the power generation efficiency of the solar cell 10 is improved.

(7) Then-type amorphous silicon layer 31c is made of silicon. Thus, the activation ratio of an n-type dopant such as phosphorous (P) or arsenide (As) can be higher than that of silicon oxide, which leads to strengthening of the internal field of the i-type amorphous silicon layer 31b. Consequently, a larger amount of photogenerated carriers created from the incident light can be taken out and the short-circuit current (I_{sc}) is improved.

(8) Then-type amorphous silicon layer 31c is made of amorphous silicon. Thus, the difference of band gap compared to the i-type amorphous silicon layer 31b can be smaller than that of crystalline silicone. As a result, the series resistance of the entire solar cell 10 caused by the different band gaps can be reduced, whereby the decrease in fill factor (F.F.) of the solar cell 10 is restricted to raise the power generation efficiency of the solar cell 10.

### Second Embodiment

### <Solar Cell Configuration>

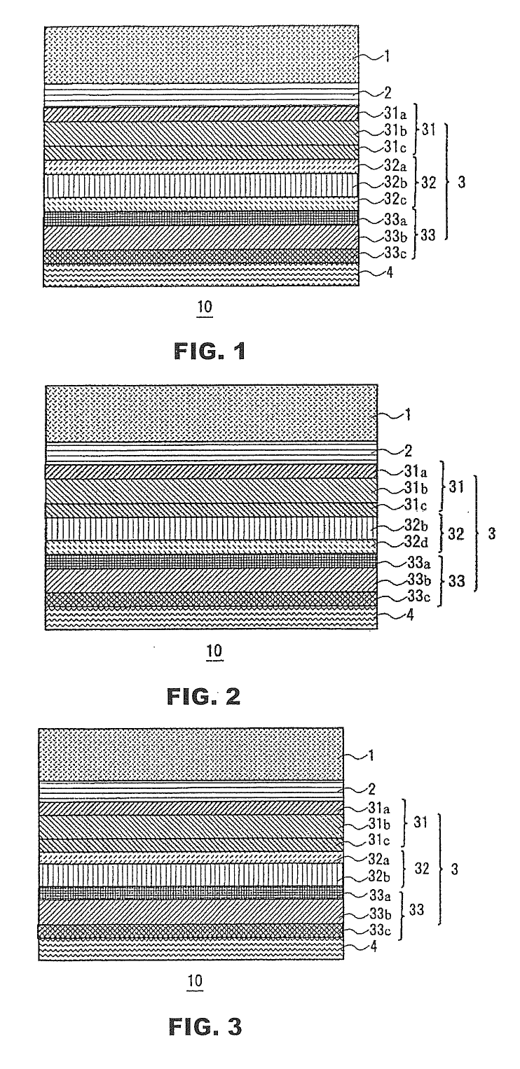

A solar cell configuration according to a second embodiment of the present invention will be described below with reference to FIG. 2. It should be noted that like reference numerals have been used to identify similar elements to those of the first embodiment, and the description thereof will not be repeated.

FIG. 2 is a sectional view of a solar cell 20 according to a second embodiment of the present invention.

As in the first embodiment, the solar cell 20 is configured to include a substrate 1, a light-receiving surface electrode layer 2, a first photoelectric conversion section 31, an intermediate layer 32, a second photoelectric conversion section 33, and a rear-side electrode layer 4, which are laminated on each other in this order from the side of the light-receiving surface.

The second embodiment is different from the first embodiment in that the intermediate layer 32 consists of an intermediate layer 32b made of n-type silicon oxide and a second layer 32d made of n-type crystalline silicone. The intermediate layer 32b and the second layer 32d are layered sequentially on the first photoelectric conversion section 31. Namely, the intermediate layer 32b is sandwiched between the n-type amorphous silicon layer 31c and the second layer 32d.

The intermediate layer 33b similar to that of the first embodiment is used here.

The second layer 32d is made of silicon doped with an n-type dopant such as phosphorous (P). In this embodiment, the film thickness of the second layer 32d is set to 20 nm, but is preferably from 10 to 50 nm.

### <Effects>

According to the second embodiment of the solar cell 20, the following effects will be obtained in addition to the similar effects (2), (3), (6), (7) and (8) of the first embodiment, whereby the power generation efficiency of the solar cell 20 can be improved.

(9) The SiO-based intermediate layer 32b is disposed between the n-type amorphous silicon layer 31c and the second layer 32d made of n-type crystalline silicon. The amorphous silicon oxide-based intermediate layer 32b has a lower refractive index than the silicon-based n-type amorphous silicon layer 31c or the second layer 32d made of n-type crystalline silicon. With the configuration where the intermediate layer 32b and the n-type amorphous silicon layer 31c are in contact with each other, it is possible to reflect the light coming from the side of the light-receiving surface and incident on the interface between the n-type silicon layer 31c and the intermediate layer 32b, and direct the light to the side of the light-receiving surface. As a result, a larger amount of light can be re-directed to the i-type amorphous silicon layer 31b to further contribute to photoelectric conversion.

In addition, since the intermediate layer 32b and the second layer 32d are in contact with each other, the light coming from the rear-side and incident on the interface between the intermediate layer 32b and the second layer 32d can be directed toward the rear-side. As a result, a larger amount of light can be confined in the i-type crystalline silicon layer 33b to further contribute to photoelectric conversion.

(10) The second layer 32d made of n-type crystalline silicon is disposed between the intermediate layer 32b and the second photoelectric conversion section layer 33. Thus, the silicon-based second layer 32d serves to prevent diffusion of oxygen from the intermediate layer 32b made of silicon oxide to the i-type amorphous silicon layer 33b. As a result, the decrease of power generation efficiency due to the decrease of film quality by the diffusion of the i-type crystalline silicon layer 33b can be restricted.

(11) The intermediate layer 32b made of n-type silicon oxide, the second layer 32d made of n-type crystalline silicon, and the p-type crystalline silicon layer 33a of the second photoelectric conversion layer 33 are sequentially laminated and in contact with each other on the n-type amorphous silicon layer 31c. Thus, the n-type amorphous silicon layer 31c and the intermediate layer 32b, both having the same kind of polarity, come in contact with each other, whereby the increase of contact resistance at the interface between the n-type amorphous silicon layer 31c and the intermediate layer 32b is prevented. Further, the second layer 32d made of n-type crystalline silicon and the p-type crystalline silicon layer 33a, both made of similar materials, are in contact with each other, whereby the increase of contact resistance at the interface between the second layer 32d and the p-type crystalline silicon layer 33a is prevented. As a result, the series resistance of the entire solar cell 10 caused by the contact resistance is decreased to restrict the decrease of the fill factor (F.F.) of the solar cell, whereby the power generation efficiency of the solar cell 10 is increased.

### Other Embodiments

While the present invention has been described above in connection with the embodiments, it will be understood that the above description, as well as the attached drawings used in the description, which constitute a part of this disclosure, are not intended to limit the invention. Persons skilled in the art will conceive of various alternative embodiments, examples, and management techniques from this disclosure.

For example, the laminated body 3 includes two photoelectric conversion sections (the first photoelectric conversion section 31 and the second photoelectric conversion section 33) in the above-described first and second embodiments, but it is not limited thereto. Specifically, the laminated body 3 may include three or more photoelectric conversion sections. In this case, the reflective layer 32 may be provided between any two adjacent photoelectric conversion sections.

Also, in the first embodiment described above, the reflective layer 32 includes the first layer 32a, the intermediate layer 32b, and the second layer 32c, but it is not limited thereto. Specifically, the reflective layer 32 may include the first layer 32a and the intermediate layer 32b, or the intermediate layer 32b and the second layer 32c.

In the first and second embodiments described above, the first photoelectric conversion section 31 includes the pin junction consisting of the p-type amorphous silicon layer 31a, the i-type amorphous silicon layer 31b, and the n-type amorphous silicon layer 31c sequentially laminated from the side of the substrate 1, but it is not limited thereto. Specifically, the first photoelectric conversion section 31 may include a pin junction in which the p-type crystalline silicon layer, the i-type crystalline silicon layer, and the n-type crystalline silicon layer are laminated from the side of the substrate 1. It is noted that the crystalline silicon includes microcrystalline silicon and polycrystalline silicon.

Further, in the first and second embodiments described above, the second photoelectric conversion section 33 includes the pin junction in which the p-type crystalline silicon layer 33a, the i-type crystalline silicon layer 33b, and the n-type crystalline silicon layer 33c are laminated from the side of the substrate 1, but it is not limited thereto. Specifically, the second photoelectric conversion section 33 may include the pin junction in which the p-type amorphous silicon layer, the i-type amorphous silicon layer, and the n-type amorphous silicon layer are laminated from the side of the substrate 1.

Further, in the above-described first and second embodiments, the first photoelectric conversion section 31 and the second photoelectric conversion section 33 include the pin junction, but it is not limited thereto. Specifically, at least one of the first and second photoelectric conversion sections 31, 33 may include a pin junction in which the p-type silicon layer and n-type silicon are laminated from the side of the substrate 1.

Further, in the first embodiment described above, the solar cell 10 is configured such that the light-receiving surface electrode layer 2, the laminated body 3, and the rear-side electrode layer 4 are sequentially laminated in this order on the substrate 1, but it is not limited thereto. Specifically, the solar cell 10 may be configured such that the rear-side electrode layer 4, the laminated body 3, and the light-receiving surface electrode layer 2 may be laminated sequentially in this order on the substrate 1.

As such, it goes without saying that the present invention may include various embodiments, etc. which are not described herein. Therefore, the technical scope of the present invention is defined only by the invention-specifying matters according to adequate scopes of the claims.

### EXAMPLES

The solar cell according to the present invention will be described more in detail hereunder by using specific examples. However, it should be noted that the present invention is not limited to the examples below and changes may be made to implement the present invention, where appropriate, without departing from the spirit of the present invention.

### Example 1

The solar cell 10 according to Example 1 as shown in FIG. 1 was made as follows.

First, over a 4 mm thick glass substrate (the glass substrate 1), a layer of SnO₂ (the light-receiving surface electrode layer 2) was formed, for example, through thermal CVD or sputtering.

Then, over the SnO₂ layer (the light-receiving surface electrode layer 2), the p-type amorphous silicon layer 31a, the i-type amorphous silicon layer 31b, and the n-type amorphous silicon layer 31c were sequentially laminated through plasma CVD to form the first cell (the first photoelectric conversion section 31).

The p-type amorphous silicon layer 31a was formed in which mixture gas of silicon-containing gas such as silane (SiH₄), disilane (Si₂H₆), and dichlorsilane (SiH₂Cl₂), p-type dopant-containing gas such as diborane (B₂H₆), and dilution gas such as hydrogen (H₂) was used as raw material gas and a film was formed. In this example, carbon-containing gas such as methane (CH₄) was added to improve light transmittance, and so the mixture gas of silane (SiH₄), methane (CH₄), diborane (B₂H₆), and hydrogen (H₂) was used as the raw material gas.

The i-type amorphous silicon layer 31b was formed in which mixture gas of silicon-containing gas such as silane (SiH₄), disilane (Si₂H₆), and dichlorsilane (SiH₂Cl₂), and dilution gas such as hydrogen (H₂) was used as raw material gas and a film was formed. In this example, the mixture gas of silane (SiH₄) and hydrogen (H₂) was used as the raw material gas.

The n-type amorphous silicon layer 31c was formed in which mixture gas of silicon-containing gas such as silane (SiH₄), disilane (Si₂H₆), and dichlorsilane (SiH₂Cl₂), n-type dopant containing gas such as phosphine (PH₃), and dilution gas such as hydrogen (H₂) was used as raw material gas and a film was formed. In this example, the mixture gas of silane (SiH₄), phosphine (PH₃), and hydrogen (H₂) was used as the raw material gas.

Next, over the first photoelectric conversion section 31, the reflective layer 32 was formed through plasma CVD. Specifically, a layer of intrinsic microcrystalline silicon (the first layer 32a), an SiO layer (the intermediate layer 32b), and a layer of intrinsic microcrystalline silicon (the third layer 32c) were sequentially laminated on the first cell (the first photoelectric conversion section 31), and the reflective layer 32 having a three-layered structure was formed.

The intrinsic microcrystalline silicon layer (the first layer 32a) and the intrinsic microcrystalline silicon layer (the third layer 32c) were formed by using the raw material gas made of mixture gas similar to that used for the i-type amorphous silicon layer 31b. In this example, the mixture gas of silane (SiH₄) and hydrogen (H₂) was used as the raw material gas.

The SiO layer (the intermediate layer 32b) was formed by using the raw material gas made of mixture gas used to form the n-type amorphous silicon layer 31c with the addition of oxygen-containing gas such as carbon dioxide (CO₂). In this example, the mixture gas of silane (SiH₄), phosphine (PH₃), hydrogen (H₂), and carbon dioxide (CO₂) was used as the raw material gas.

Next, over the reflective layer 32, the p-type microcrystalline layer 33a, the i-type microcrystalline silicon layer 33b, and the n-type microcrystalline silicon layer 33c are laminated through plasma CVD, and the second photoelectric conversion section 33 was formed.

The p-type microcrystalline silicon layer (the p-type crystalline silicon layer 33a) was formed using the raw material gas made of mixture gas similar to that used to form the p-type amorphous silicon layer 31a. In this example, the mixture gas of silane (SiH₄), methane (CH₄), diborane (B₂H₆), and hydrogen (H₂) was used as the raw material gas.

The i-type microcrystalline silicon layer (the i-type crystalline silicon layer 33b) was formed using the raw material gas made of mixture gas similar to that used to form the i-type amorphous silicon layer 31b. In this example, the mixture gas of silane (SiH₄) and hydrogen (H₂) was used as the raw material gas.

The n-type microcrystalline silicon layer (the n-type crystalline silicon layer 33c) was formed by using the raw material gas made of mixture gas similar to that used to form the n-type amorphous silicon layer 31c. In this example, the mixture gas of silane (SiH₄), phosphine (PH₃), and hydrogen (H₂) was used as the raw material gas.

Regarding the intrinsic microcrystalline silicon layer (the first layer 32a), the intrinsic microcrystalline silicon layer (the third layer 32c), the p-type microcrystalline silicon layer (the p-type crystalline silicon layer 33a), the i-type microcrystalline silicon layer (the i-type crystalline silicon layer 33b) and the n-type microcrystalline silicon layer (the n-type crystalline silicon layer 33c), crystallization is carried out, for example, by raising a hydrogen dilution ratio or increasing RF power compared to the p-type amorphous silicon layer 31a, the i-type amorphous silicon layer 31b, and the n-type amorphous silicon layer 31c, respectively.

Next, over the second photoelectric conversion section 33, an ZnO layer and an Ag layer (the rear-side electrode layer 4) were formed through sputtering. It is noted that the ZnO layer and the Ag layer (the rear-side electrode 4) were set to have a thickness of 90 nm and 200 nm, respectively.

The above-described first photoelectric conversion section 31, the reflective layer 32, and the second photoelectric conversion layer 33 were formed with the conditions shown in TABLE 1.

TABLE 1

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE | 180 | SiH₄: 300 | 106 | 10 | 15 |
| PHOTOELECTRIC | AMORPHOUS | | CH₄: 300 | | | |
| CONVERSION | SILICON LAYER | | H₂: 2000 | | | |
| SECTION 31 | 31a | | B₂H₆: 3 | | | |
| | i-TYPE | 200 | SiH₄: 300 | 106 | 20 | 200 |
| | AMORPHOUS | | H₂: 2000 | | | |
| | SILICON LAYER | | | | | |
| | 31b | | | | | |
| | n-TYPE | 180 | SiH₄: 300 | 133 | 20 | 30 |
| | AMORPHOUS | | H₂: 300 | | | |
| | SILICON LAYER | | PH₃: 5 | | | |
| | 31c | | | | | |
| REFLECTIVE | i-TYPE | 180 | SiH₄: 20 | 250 | 30 | 30 |
| LAYER 32 | CRYSTALLINE | | H₂: 2000 | | | |
| | SILICON LAYER | | | | | |
| | (FIRST LAYER 32a) | | | | | |
| | n-TYPE | 180 | SiH₄: 8 | 250 | 30 | 50 |
| | AMORPHOUS | | H₂: 1600 | | | |
| | SILICON OXIDE | | PH₃: 0.2 | | | |
| | LAYER | | CO₂: 12 | | | |
| | (INTERMEDIATE | | | | | |
| | LAYER 32b) | | | | | |
| | i-TYPE | 180 | SiH₄: 20 | 250 | 30 | 30 |
| | CRYSTALLINE | | H₂: 2000 | | | |
| | SILICON LAYER | | | | | |
| | (SECOND LAYER 33c) | | | | | |
| SECOND | n-TYPE | 180 | SiH₄: 10 | 106 | 10 | 30 |
| PHOTOELECTRIC | CRYSTALLINE | | H₂: 2000 | | | |
| CONVERSION | SILICON LAYER | | B₂H₆: 0.1 | | | |
| SECTION 33 | 33a | | | | | |
| | i-TYPE | 200 | SiH₄: 100 | 133 | 20 | 2000 |
| | CRYSTALLINE | | H₂: 2000 | | | |
| | SILICON LAYER | | | | | |
| | 33b | | | | | |
| | n-TYPE | 200 | SiH₄: 10 | 133 | 20 | 20 |
| | CRYSTALLINE | | H₂: 2000 | | | |
| | SILICON LAYER | | PH₃: 0.2 | | | |
| | 33c | | | | | |

Thus, in Example 1, the solar cell 10 including the reflective layer 32 having the SiO layer (the intermediate layer 32b) between the first and second photoelectric conversion sections 31, 33 was formed. Also, the intrinsic microcrystalline silicon layer (the first layer 32a) was interleaved between the SiO layer (the intermediate layer 32b) and the first photoelectric conversion section 31, and the intrinsic microcrystalline silicon layer (the second layer 32c) was interleaved between the SiO layer (the intermediate layer 32b) and the second photoelectric conversion section 33.

### Example 2

The solar cell 10 according Example 2 was formed in the same manner as in Example 1 except for the configuration of the reflective layer 32.

After the first photoelectric section 31 was formed as in Example 1, the reflective layer 32 was formed through plasma CVD over the first photoelectric conversion section 31. Specifically, the reflective layer 32 having a two-layered structure was formed by sequentially laminating the intrinsic microcrystalline silicon layer (the first layer 32a) and the SiO layer (the intermediate layer 32b) on the first photoelectric conversion section 31.

The intrinsic microcrystalline silicon layer (the first layer 32a) and the SiO layer (the intermediate layer 32b) were formed in the same manner as in Example 1.

Then, over the reflective layer 32, the second photoelectric conversion section 33 and the ZnO and Ag layers (the rear-side electrode 4) were sequentially formed.

The above-described first photoelectric conversion section 31, the reflective layer 32, and the second photoelectric conversion layer 33 were formed with the conditions shown in TABLE 2.

TABLE 2

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE | 180 | SiH₄: 300 | 106 | 10 | 15 |
| PHOTOELECTRIC | AMORPHOUS | | CH₄: 300 | | | |
| CONVERSION | SILICON LAYER | | H₂: 2000 | | | |
| SECTION 31 | 31a | | B₂H₆: 3 | | | |
| | i-TYPE | 200 | SiH₄: 300 | 106 | 20 | 200 |
| | AMORPHOUS | | H₂: 2000 | | | |
| | SILICON LAYER | | | | | |
| | 31b | | | | | |
| | n-TYPE | 180 | SiH₄: 300 | 133 | 20 | 30 |
| | AMORPHOUS | | H₂: 300 | | | |
| | SILICON LAYER | | PH₃: 5 | | | |
| | 31c | | | | | |
| REFLECTIVE | i-TYPE | 180 | SiH₄: 20 | 250 | 30 | 30 |
| LAYER 32 | CRYSTALLINE | | H₂: 2000 | | | |
| | SILICON LAYER | | | | | |
| | (FIRST LAYER 32a) | | | | | |
| | n-TYPE | 180 | SiH₄: 8 | 250 | 30 | 50 |
| | AMORPHOUS | | H₂: 1600 | | | |
| | SILICON OXIDE | | PH₃: 0.2 | | | |
| | LAYER | | CO₂: 12 | | | |
| | (INTERMEDIATE | | | | | |
| | LAYER 32b) | | | | | |
| SECOND | p-TYPE | 180 | SiH₄: 10 | 106 | 10 | 30 |
| PHOTOELECTRIC | CRYSTALLINE | | H₂: 2000 | | | |
| CONVERSION | SILICON LAYER | | B₂H₆: 0.1 | | | |
| SECTION 33 | 33a | | | | | |
| | i-TYPE | 200 | SiH₄: 100 | 133 | 20 | 2000 |
| | AMORPHOUS | | H₂: 2000 | | | |
| | SILICON LAYER | | | | | |
| | 33b | | | | | |
| | n-TYPE | 200 | SiH₄: 10 | 133 | 20 | 20 |
| | CRYSTALLINE | | H₂: 2000 | | | |
| | SILICON LAYER | | PH₃: 0.2 | | | |
| | 33c | | | | | |

Thus, in Example 2, the solar cell 10 including the reflective layer 32 having the SiO layer (the intermediate layer 32b) between the first and second photoelectric conversion sections 31, 33 was formed. Also, the intrinsic microcrystalline silicon layer (the first layer 32a) was interleaved between the SiO layer (the intermediate layer 32b) and the first photoelectric conversion section 31.

### Example 3

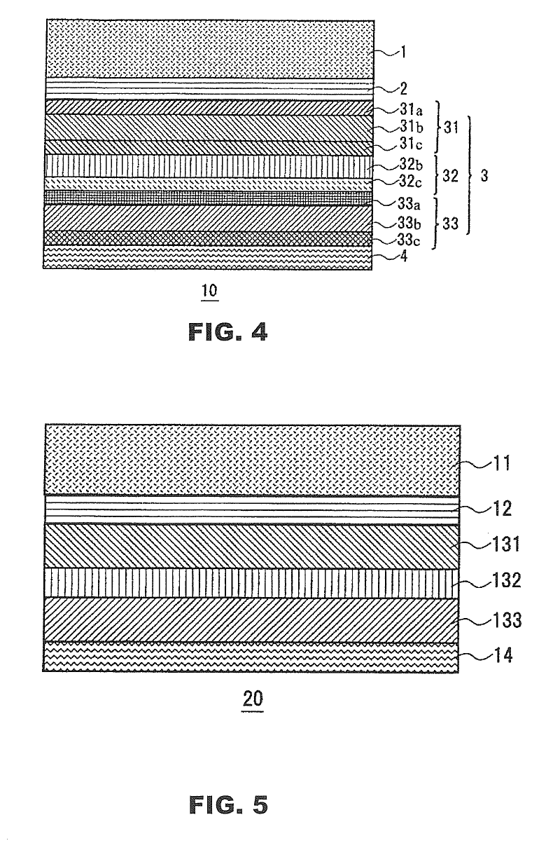

The solar cell 10 according to Example 3 was formed as shown in FIG. 4 in the same manner as in Example 1 except for the configuration of the reflective layer 32.

After the first photoelectric section 31 was formed as in Example 1, the reflective layer 32 was formed through plasma CVD over the first photoelectric conversion section 31. Specifically, the reflective layer 32 having a two-layered structure was formed by sequentially laminating the SiO layer (the intermediate layer 32b) and the intrinsic microcrystalline silicon layer (the second layer 32c) on the first photoelectric conversion section 31.

The SiO layer (the intermediate layer 32b) and the intrinsic microcrystalline silicon layer (the first layer 32c) were formed in the same manner as in Example 1.

Then, over the reflective layer 32, the second photoelectric conversion section 33, the ZnO and Ag layers (the rear-side electrode 4) were sequentially formed.

The above-described first photoelectric conversion section 31, the reflective layer 32, and the second photoelectric conversion layer 33 were formed with the conditions shown in TABLE 3.

TABLE 3

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE AMORPHOUS | 180 | SiH₄: 300 | 106 | 10 | 15 |
| PHOTOELECTRIC | SILICON LAYER 31a | | CH₄: 300 | | | |
| CONVERSION | | | H₂: 2000 | | | |
| SECTION 31 | | | B₂H₆: 3 | | | |
| | i-TYPE AMORPHOUS | 200 | SiH₄: 300 | 106 | 20 | 200 |
| | SILICON LAYER 31b | | H₂: 2000 | | | |
| | n-TYPE AMORPHOUS | 180 | SiH₄: 300 | 133 | 20 | 30 |
| | SILICON LAYER 31c | | H₂: 300 | | | |
| | | | PH₃: 5 | | | |
| REFLECTIVE | n-TYPE CRYSTALLINE | 180 | SiH₄: 8 | 250 | 30 | 50 |
| LAYER 32 | SILICON OXIDE LAYER | | H₂: 1600 | | | |
| | (INTERMEDIATE | | PH₃: 0.2 | | | |
| | LAYER 32b) | | CO₂: 12 | | | |
| | i-TYPE AMORPHOUS | 180 | SiH₄: 20 | 250 | 30 | 30 |
| | SILICON OXIDE LAYER | | H₂: 2000 | | | |
| | (SECOND LAYER 32c) | | | | | |
| SECOND | p-TYPE CRYSTALLINE | 180 | SiH₄: 10 | 106 | 10 | 30 |
| PHOTOELECTRIC | SILICON LAYER 33a | | H₂: 2000 | | | |
| CONVERSION | | | B₂H₆: 0.1 | | | |
| SECTION 33 | i-TYPE | 200 | SiH₄: 100 | 133 | 20 | 2000 |
| | CRYSTALLINESILICON | | H₂: 2000 | | | |
| | LAYER 33b | | | | | |
| | n-TYPE CRYSTALLINE | 200 | SiH₄: 10 | 133 | 20 | 20 |
| | SILICON LAYER 33c | | H₂: 2000 | | | |
| | | | PH₃: 0.2 | | | |

Thus, in Example 3, the solar cell 10 including the reflective layer 32 having the intermediate layer 32b between the first and second photoelectric conversion sections 31, 33 was formed. Also, the intrinsic microcrystalline silicon layer (the second layer 32c) was interleaved between the Sb layer (the intermediate layer 32b) and the second photoelectric conversion section 33.

### Comparative Example

A solar cell 20 according to Comparative Example shown in FIG. 5 was formed as follows.

First, in the same manner as Example 1 described above, the SnO₂ layer (the light-receiving surface electrode layer 12) and a first photoelectric conversion section 131 were sequentially formed on the glass substrate (the substrate 11) having a thickness of 4 mm.

Next, a reflective layer 132 was formed through plasma CVD over the first photoelectric conversion section 131. In this Comparative Example 1, only the SiO layer was formed over the first photoelectric conversion section 131 to serve as a reflective layer 132.

Next, in the same manner as described in Example 1 above, the second photoelectric conversion section 133, the ZnO and Ag layers (the rear-side electrode layer 14) were sequentially formed over the reflective layer 132.

The above-described first photoelectric conversion section 131, the reflective layer 132, and the second photoelectric conversion layer 133 were formed with the conditions shown in TABLE 4. It is noted that the first and second photoelectric conversion sections 131, 133 were formed with the same conditions as those used in Example 1. The thickness of the ZnO layer and the Ag layer (the rear-side electrode layer 14) were 90 nm and 200 nm, respectively, as in Example 1.

TABLE 4

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE AMORPHOUS | 180 | SiH₄: 300 | 106 | 10 | 15 |
| PHOTOELECTRIC | SILICON LAYER | | CH₄: 300 | | | |
| CONVERSION | | | H₂: 2000 | | | |
| SECTION 131 | | | B₂H₆: 3 | | | |
| | i-TYPE AMORPHOUS | 200 | SiH₄: 300 | 106 | 20 | 200 |
| | SILICON LAYER | | H₂: 2000 | | | |
| | n-TYPE AMORPHOUS | 180 | SiH₄: 300 | 133 | 20 | 30 |
| | SILICON LAYER | | H₂: 300 | | | |
| | | | PH₃: 5 | | | |
| REFLECTIVE | n-TYPE AMORPHOUS | 180 | SiH₄: 8 | 250 | 30 | 50 |
| LAYER 132 | SILICON OXIDE LAYER | | H₂: 1600 | | | |
| | | | PH₃: 0.2 | | | |
| | | | CO₂: 12 | | | |
| SECOND | p-TYPE CRYSTALLINE | 180 | SiH₄: 10 | 106 | 10 | 30 |
| PHOTOELECTRIC | SILICON LAYER | | H₂: 2000 | | | |
| CONVERSION | | | B₂H₆: 0.1 | | | |
| SECTION 133 | i-TYPE | 200 | SiH₄: 100 | 133 | 20 | 2000 |
| | CRYSTALLINESILICON | | H₂: 2000 | | | |
| | LAYER | | | | | |
| | n-TYPE CRYSTALLINE | 200 | SiH₄: 10 | 133 | 20 | 20 |
| | SILICON LAYER | | H₂: 2000 | | | |
| | | | PH₃: 0.2 | | | |

Thus, the solar cell 20 including the reflective layer 132 having the SiO layer between the first photoelectric conversion section 131 and the second photoelectric conversion section 133 was formed in the Comparative Example.

### <Characteristic Evaluation>

Regarding the solar cells according to Examples 1, 2, and 3, and Comparative Example, characteristic values including the open voltage, the short-circuit current, the fill factor, and the efficiency of power generation were compared. The results of comparison are shown in Table 5. It is noted that the characteristic values of the Comparative Example are normalized to 1.00 in Table 5.

TABLE 5

| | | Isc | F.F. | Eff |
|---|---|---|---|---|
| | Voc | (SHORT- | (FILL | (POWER |
| | (OPEN | CIRCUIT | FAC- | GENERATION |
| | 0VOLTAGE) | CURRENT) | TOR) | EFFICIENCY) |
| EXAM- | 1.01 | 0.99 | 1.07 | 1.07 |
| PLE 1 | | | | |
| EXAM- | 1.00 | 0.98 | 1.04 | 1.02 |
| PLE 2 | | | | |
| EXAM- | 1.01 | 1.01 | 1.04 | 1.06 |
| PLE 3 | | | | |
| COMPAR- | 1.00 | 1.00 | 1.00 | 1.00 |
| ATIVE | | | | |
| EXAMPLE | | | | |

As shown in Table 5, it was confirmed that the fill factors and the power generation efficiencies of Examples 1, 2, and 3 were greater than those of Comparative Example.

Regarding the fill factor, it was confirmed that the fill factors of the solar cell 10 according to Examples 1, 2, and 3 were increased by providing at least either one of the first layer (32a) between the SiO layer (the intermediate layer 32b) and the first photoelectric conversion section 31, or the second layer (32c) between the SiO layer (the intermediate layer 32b) and the second photoelectric conversion section 33. This may be caused by the decrease of contact resistance at the interface between the SiO layer (the intermediate layer 32b) and the first photoelectric conversion section 31, or between the SiO layer (the intermediate layer 32b) and the second layer (32c), by provision of the first layer (32a) or the second layer (32c), which might lead to the decrease of the series resistance of the solar cell 10.

Therefore, in any Example, it was possible to take out larger power by improving the fill factor. Although the short-circuit current was smaller in Examples 1 and 2 than Comparative Example, it was confirmed that the power generation efficiency was more improved than Comparative Example.

It is noted that although Examples 1, 2, and 3 according to the above-described first embodiment and Comparative Example were prepared and characteristic evaluation thereof were carried out, the characteristic evaluation of the second embodiment was not carried out. However, since the effects (2), (3), (6), (7), and (8) were obtained in the second embodiment as they were in the first embodiment, better characteristics might be provided for the second embodiment than Comparative Example.

The example according to the second embodiment shown in FIG. 2 may be configured in the same manner as Example 1 except for the reflective layer 32. Similar to Example 1, after the first photoelectric conversion section 31 was formed, the reflective layer 32 can be formed through plasma CVD over the first photoelectric conversion section 31. Specifically, by laminating the SiO layer (the intermediate layer 32b) and the n-type microcrystalline silicon layer (the second layer 32d) sequentially on the first photoelectric conversion section 31, the reflective layer 32 having a two-layered structure can be formed.

The SiO layer (the intermediate layer 32b) and the n-type microcrystalline silicon layer (the second layer 32d) may be formed in the same manner as the SiO layer (the intermediate layer 32b) and the n-type microcrystalline silicon layer (the n-type crystalline silicon layer 33c) of Example 1. The first photoelectric conversion section 31, the reflective layer 32, and the second photoelectric conversion section 33 can be formed with the conditions shown in Table 6.

TABLE 6

| | | SUBSTRATE | GAS FLOW | REACTION | RF | |
|---|---|---|---|---|---|---|
| | | TEMPERATURE | RATE | PRESSURE | POWER | THICKNESS |
| | | (° C.) | (sccm) | (Pa) | (W) | (nm) |
| FIRST | p-TYPE AMORPHOUS | 180 | SiH₄: 300 | 106 | 10 | 15 |
| PHOTOELECTRIC | SILICON LAYER 31a | | CH₄: 300 | | | |
| CONVERSION | | | H₂: 2000 | | | |
| SECTION 31 | | | B₂H₆: 3 | | | |
| | i-TYPE AMORPHOUS | 200 | SiH₄: 300 | 106 | 20 | 200 |
| | SILICON LAYER 31b | | H₂: 2000 | | | |
| | n-TYPE AMORPHOUS | 180 | SiH₄: 300 | 133 | 20 | 20 |
| | SILICON LAYER 31c | | H₂: 300 | | | |
| | | | PH₃: 5 | | | |
| REFLECTIVE | n-TYPE AMORPHOUS | 180 | SiH₄: 8 | 250 | 30 | 50 |
| LAYER 32 | SILICON OXIDE LAYER | | H₂: 1600 | | | |
| | (INTERMEDIATE | | PH₃: 0.2 | | | |
| | LAYER 32b) | | CO₂: 12 | | | |
| | n-TYPE CRYSTALLINE | 180 | SiH₄: 10 | 250 | 30 | 20 |
| | SILICON LAYER | | H₂: 2000 | | | |
| | (SECOND LAYER 32d) | | PH₃: 0.2 | | | |
| SECOND | p-TYPE CRYSTALLINE | 180 | SiH₄: 10 | 106 | 10 | 30 |
| PHOTOELECTRIC | SILICON LAYER 33a | | H₂: 2000 | | | |
| CONVERSION | | | B₂H₆: 0.1 | | | |
| SECTION 33 | i-TYPE | 200 | SiH₄: 100 | 133 | 20 | 2000 |
| | CRYSTALLINESILICON | | H₂: 2000 | | | |
| | LAYER 33b | | | | | |
| | n-TYPE CRYSTALLINE | 200 | SiH₄: 10 | 133 | 20 | 20 |
| | SILICON LAYER 33c | | H₂: 2000 | | | |
| | | | PH₃: 0.2 | | | |

Thus, the solar cell 20 having the intermediate layer 32b and the n-type crystalline silicon layer 32d between the first and second photoelectric conversion sections 32, 33 can be formed.

The present invention is applicable to solar cells.

### PARTS LIST

1, 11: SUBSTRATE
2, 12: LIGHT-RECEIVING SURFACE ELECTRODE LAYER
3: LAMINATED BODY
31, 131: FIRST PHOTOELECTRIC CONVERSION SECTION
32, 132: REFLECTIVE LAYER
33, 133: SECOND PHOTOELECTRIC CONVERSION SECTION
4,14: REAR-SIDE ELECTRODE LAYER
10, 20: SOLAR CELL

1. A solar cell, comprising:
a light-receiving surface electrode layer;
a first photoelectric conversion section laminated on said light-receiving surface electrode layer;
a reflective layer laminated on said first photoelectric conversion section and having an SiO layer and a silicon layer;
a second photoelectric conversion section laminated on said reflective layer; and
a rear-side electrode layer laminated on said second photoelectric conversion section, wherein
said reflective layer includes a first silicon layer being in contact with said first photoelectric conversion section, a second silicon layer being in contact with said second photoelectric conversion layer, and an SiO layer provided between said first silicon layer and said second silicon layer.

2. The solar cell according to claim 1, wherein said SiO layer is amorphous

3. The solar cell according to claim 1, wherein said silicon layer is crystalline silicon.

4. The solar cell according to claim 1, wherein
said SiO layer has a refractive index less than 2.4 for 550 nm wavelength of light.

5. The solar cell according to claim 1, wherein said second photoelectric conversion section is crystalline.

6. The solar cell according to claim 1, wherein said first photoelectric conversion section is amorphous.

7. The solar cell according to claim 1, wherein said silicon layer is made of intrinsic silicon.

8. The solar cell according to claim 1, wherein said silicon layer is one-conductivity type silicon.
